(19) United States
(12) Patent Application Publication
(10) Pub. No.: US 2007/0127738 A1
(43) Pub. Date: Jun. 7, 2007

(54) Audio signal processing device and audio signal reproduction system

(75) Inventors: Yuji Yamada, Tokyo (JP); Koyuru Okimoto, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Sony Corporation, Tokyo (JP)

(21) Appl. No.: 10/581,096

(22) PCT Filed: Dec. 13, 2004
(86) PCT No.: PCT/JP04/18600

§ 371 Date: May 31, 2006

(30) Foreign Application Priority Data
Dec. 15, 2003 (JP) 2003-417334

(51) Int. Cl. H03G 5/00

(52) U.S. Cl. 381/98

(57) ABSTRACT

The present invention is directed to an audio signal reproducing system comprising a speaker system including at least two drive units or more which are divided or separated by frequency band. In this system (1), a signal processing unit (3) serves to add inverse characteristic to an inputted digital audio signal as correction characteristic of impulse response of speaker system (7). Thereafter, a D/A converter converts the digital audio signal thus obtained back into an analog signal. A power amplifier (5) amplifiers the analog signal thus obtained to deliver the analog signal thus amplified to the speaker system (7). The speaker system (7) outputs a signal at low frequency band that a LPF (8) has passed as sound wave of low pitched sound from drive surface (9a) of a low frequency drive unit (9), and outputs a signal at high frequency band that a HPF (10) has passed as sound wave of high pitched sound from drive surface (11a) of a high frequency drive unit (11).

### TECHNICAL FIELD

The present invention relates to a speaker and headphone system which have satisfactory sound image localization characteristic, and an audio signal processing apparatus and an audio signal reproducing system in the case of allowing satisfactory sound image to undergo localization such that there results an arbitrary position.

This Application claims priority of Japanese Patent Application No. 2003-417334, filed on Dec. 15, 2003, the entirety of which is incorporated by reference herein.

### BACKGROUND ART

In the case of reproducing an audio or acoustic signal by a speaker unit, in order to obtain satisfactory frequency characteristic over a broad frequency band, since frequency bands in which satisfactorily reproduction can be performed are different from each other in accordance with respective apertures every drive units or speaker units, there is used multiway speaker system including plural drive units such as woofer, tweeter and/or super-tweeter, etc.

In the multiway speaker system, when drive surfaces of respective drive units do not flush with each other, propagation delay time difference or differences take place between reproduction sounds of respective reproduction frequency bands. Explanation will be given by taking an example of a two-way speaker system 106 composed of a unit for driving a signal at low frequency band (hereinafter simply refereed to as a low frequency drive unit or driver) 102 connected to a LPF 101 for allowing low frequency band of an analog audio signal delivered from an input terminal 100 to be passed therethrough, and a unit for driving a signal at high frequency band (hereinafter simply referred to as a high frequency drive unit or driver) 104 connected to a HPF 103 for allowing high frequency band of an analog audio signal from the input terminal 100 to be passed therethrough as shown in FIG. 1. In the two-way speaker system 106 shown in FIG. 1, since drive surface (acoustic center) 102a of the low frequency drive unit 102 and drive surface (acoustic center) 104a of the high frequency drive unit 104 do not flush with each other, propagation delay time difference At takes place between at low frequency band and at high frequency band of reproduction frequency. When drive surfaces 102a, 104a of the respective drive units 102, 104 do not flush with each other in this way, phases of wave fronts of sound waves would shift depending upon reproduction frequency band. This is not preferable in order to obtain satisfactory sound image localization.

For this reason, in actual multiway speaker systems, there are instances where device for allowing drive surfaces of respective drive units to flush with each other is implemented in order to solve the above-mentioned problem. For example, in a two-way speaker system 107, as shown in FIG. 2, attachment position of high frequency drive unit 104 is positionally shifted in a backward direction indicated by arrow K in order to allow drive surface 104a of the high frequency drive unit 104 connected to HPF 103 to flush with drive surface 102a of low frequency drive unit 102 connected to LPF 101. In this case, propagation delay time difference Δt can become close to zero so that improvement is made. However, since the attachment position of the high frequency drive unit 104 is positionally shifted in a backward direction of the direction indicated by arrow K in FIG. 2, the structure of an enclosure 108 of the speaker box becomes complicated. For this reason, the cost required for preparing the speaker system is increased. As a result, the speaker system becomes expensive. Moreover, there were problems such as deterioration of phase characteristic at crossover frequency based on the characteristic of the divided or separated filters for input signal to respective drive units such as high frequency drive unit 104 and low frequency drive unit 102, etc.

Further, an example of another multiway speaker system is shown in FIG. 3. In the speaker system 109, drive unit 104 for driving a signal at high frequency band an drive unit 102 for driving a signal at low frequency band are axially disposed so that their drive axes flush with each other. In this example, the high frequency drive unit 104 is fixed at enclosure (speaker box) 108 by support member 104b. In such multiway speaker system 109 of the coaxial arrangement, since the high frequency drive unit 104 is disposed at the front surface of the low frequency drive unit 102 from a structural point of view, drive surface of sound wave of the high frequency drive unit 104 and drive surface of sound wave of the low frequency band drive unit 102 are shifted so that propagation delay time difference Δt takes place. For this reason, phases of wave fronts of sound waves would be necessarily shifted in dependency upon reproduction frequency band. This is not preferable in order to obtain satisfactory sound image localization.

Then, the system for realizing an arbitrary sound image localization by two speakers will be explained. As sound followed by image such as movie, etc., there are many cases where multi-channel audio signals are used. Such multi-channel audio signals are recorded on the assumption that they are reproduced by speakers or speaker placed at both sides or the center of screen or display unit on which image is displayed, and speaker or speakers placed at backward position or both lateral sides of listener, etc. However, there is restriction in the speaker layout. Thus, there is the problem that listener who can provide a large number of speakers for reproducing sounds of many channels at listening is limited. In view of the above, it is proposed that a large number of sound images by input audio signals of many channels are caused to undergo localization such that there results an arbitrary position around the listener by a lesser number of speakers, e.g., two speakers.

An example for constituting many virtual speaker sound sources by using these two speakers will be explained with reference to FIGS. 4 and 5. The speaker unit 110 shown in FIG. 4 is supplied with an analog audio signal from an input terminal 111. The analog audio signal is converted into a digital audio signal at an A/D converter circuit 112. Then, the digital audio signal thus obtained is delivered to a signal processing unit 113. At the signal processing unit 113, an audio signal for Lch and an audio signal for Rch are processed on the basis of the principle which will be described later by making reference to FIG. 5 to convert processed outputs into analog audio signals at a D/A converter 114L and a D/A converter 114R thereafter to amplify the analog audio signals thus obtained at amplifiers 115L and 115R thereafter to deliver the signals thus obtained to speakers 116L and 116R. Thus, sound waves are outputted from the speakers 116L and 116R.

Then, the principle of the speaker unit 110 will be explained with reference to FIG. 5. In order to virtually reproduce sound source SO by using sound sources SL and SR, when transfer functions of audio signals arriving from the sound source SL to left ear YL and right ear YR of listener M are respectively assumed as HLL and HLR, transfer functions of audio signals arriving from the sound source SR to left ear YL and right ear YR of listener M are respectively assumed as HRL and HRR, and transfer functions of audio signals arriving from the sound source SO to left ear YL and right ear YR of listener M are respectively assumed as HOL and HOR, the transfer relationship between the sound source SL and the sound source SO is represented by the formula (1) described below, and the transfer relationship between the sound source SR and the sound source SO is represented by the formula (2) described below.
SL={(HOL×HRR−HOR×HRL)/(HLL×HRR−HLR×HRL)}×SO (1)
SR={(HOR×HLL−HOL×HLR)/(HLL×HRR−HLR×HRL)}×SO (2)

Accordingly, synthetic audio signal Sb1 for left ear is obtained by passing audio signal Sao of the sound source SO through a filter which realizes the transfer function portion of the formula (1), and synthetic audio signal Sbr for right ear is obtained by passing audio signal Sao through a filter which realizes the transfer function portion of the formula (2). By driving two speakers disposed at positions of the sound sources SL and SR by synthetic audio signals Sbl, Sbr for left ear and right ear, it is possible to allow virtual sound source as if audio signal Sao is produced from the position of the sound source SO caused to undergo localization.

Further, with respect to a large number of virtual sound sources, it is sufficient to execute the above-described processing by the number of virtual sound sources. Since many virtual speaker sound sources can be constituted from a lesser number of speaker sound sources by the above-mentioned method, the number of actual speakers can be reduced.

In the case where such a method is used, there is the problem that effect may vary depending upon the characteristic of speaker for reproduction. Namely, the case where a desired characteristic can be obtained by the transfer functions shown in the formulas (1) and (2) is the case where the characteristic of reproduction speaker is transfer function H=1. In reproduction in general speaker, since the characteristic of that speaker is added, deviation of the characteristic would take place. As a result, there was the problem that sound quality or quality of sound image caused to undergo localization may be deteriorated.

Moreover, the Applicant of this Application has disclosed, in the Japanese Patent Application Laid Open No. 1997-215084 publication, an acoustic reproducing apparatus in which speaker is disposed in the vicinity of ear of listener in the state which is not in contact with the ear of listener to give (apply), to the speaker, an audio signal in which inverse characteristic of the transfer characteristic between the speaker and ear of user has been added so that frequency characteristic of reproduced sound is caused to be flat without undergoing influence of the transfer characteristic while maintaining the state which is not in contact with ear.

As described above, in the multiway speaker system, there was the problem that when drive surfaces of respective drive units do not flush with each other, since propagation delay time difference takes place at respective reproduction frequency bands so that phases of wave fronts are shifted, there results obstacle to satisfactory sound image localization.

Moreover, in order to avoid the above-mentioned problem, even in the case where there is employed a method in which respective drive units are attached in the state where their drive surfaces are positionally shifted to mechanically adjust phases so that they are flush with each other, there were problems that the cost is increased by complicated attachment structure of speaker units, and/or phase characteristic at crossover frequency is disturbed by band-limit filters with respect to respective speaker units, thus to give bad influence to sound quality and/or sound image localization. Further, in the system where two speakers are used to allow sound image to undergo localization such that there results an arbitrary position at the outside of the speaker, quality of sound image localization is disadvantageously deteriorated by difference between characteristics of reproduction speakers.

In addition, in the acoustic reproducing apparatus described in the above-mentioned publication, the speaker portion is not caused to be directly attached to ear of listener in acoustic device that only listener himself uses like headphone device to add the inverse characteristic of the transfer characteristic to the ear of the listener thus to deliver an audio signal to the speaker portion, whereas the influence on the phase characteristic at crossover frequency in the multiway speaker system is not disclosed by any means.

### DISCLOSURE OF THE INVENTION

### Problems to be Solved by the Invention

An object of the present invention is to provide a novel audio signal processing apparatus and a novel audio signal reproducing system which can solve or eliminate problems that prior arts as described above have.

Another object of the present invention is to provide an audio signal processing apparatus and an audio signal reproducing system in which there is no necessity of allowing drive surfaces of respective drive units to flush with each other in the multiway speaker system to improve delay time difference or differences between speaker units, thus resultantly making it possible to improve sound image localization.

### MEANS FOR SOLVING THE PROBLEMS

The present invention is directed to an audio signal processing apparatus adapted for delivering an audio signal to a speaker system including at least two drive units or more which are divided or separated by frequency band, the audio signal processing apparatus comprising: filter means for processing an input audio signal on the basis of correction characteristic of impulse response of the speaker system in order to correct shift between phases of respective sound waves radiated from respective drive surfaces of the two drive units or more of the speaker system, thus to deliver, to the speaker system, an audio output signal which has been caused to undergo signal processing by the filter means.

The filter means processes an input audio signal on the basis of correction characteristic of impulse response, e.g., inverse characteristic of impulse response of the speaker system.

Moreover, the present invention is directed to an audio signal processing apparatus adapted for delivering an audio signal to a speaker system including at least two drive units or more which are divided or separated by frequency band, the audio signal processing apparatus comprising: filter means comprised of FIR filter for processing an input audio signal on the basis of correction characteristic of impulse response of the speaker system in order to correct shift between phases of respective sound waves radiated from respective drive surfaces of the two drive units or more of the speaker system, thus to deliver, to the speaker system, an audio output signal which has been caused to undergo signal processing by the filter means comprised of FIR filter.

The filter means comprised of FIR filter processes an input audio signal on the basis of correction characteristic of impulse response, e.g., inverse characteristic of impulse response of the speaker system.

Further, the present invention is directed to an audio signal processing apparatus adapted for delivering an audio signal to a speaker system at least including two drive units or more which are divided or separated by frequency band, the audio signal processing apparatus comprising: first filter means having an arbitrary transmission characteristic which has been determined by measurement or calculation in advance; and second filter means having correction characteristic of impulse response of the speaker system in order to correct shift between phases of respective sound waves radiated from respective drive surfaces of the two drive units or more of the speaker system, thus to deliver, to the speaker system, an audio output signal from the second filter means.

The first filter means serves to add arbitrary characteristic which has been determined in advance by measurement or calculation to input audio signal, and the second filter means serves to add correction characteristic of impulse response of the speaker system to output signal of the first filter means.

Furthermore, the present invention is directed to an audio signal processing apparatus adapted for delivering an audio signal to a speaker system including at least two drive units or more which are divided or separated by frequency band, the audio signal processing apparatus comprising: first filter means having frequency characteristic where group delay characteristic which has been determined in advance by measurement or calculation is constant; and second filter means having correction characteristic of impulse response of the speaker system in order to correct shift between phases of respective sound waves radiated from respective drive surfaces of the two drive units or more of the speaker system, thus to deliver, to the speaker system, an audio output signal from the second filter means.

The first filter means serves to add, to input audio signal, frequency characteristic where group delay characteristic which has been determined by measurement or calculation in advance is constant, and the second filter means serves to add correction characteristic of impulse response of the speaker system to output signal of the first filter means.

Furthermore, the present invention is directed to an audio signal processing apparatus adapted for delivering an audio signal to a speaker system including at least two drive units or more which are divided or separated by frequency band, the audio signal processing apparatus comprising: first filter means having characteristic for conducting a control such that sound image localization position in the case where an input audio signal is reproduced by plural speakers results in an arbitrary position; and second filter means having correction characteristic of impulse response of the speaker system in order to correct shift between phases of respective sound waves radiated from respective drive surfaces of the two drive units or more of the speaker system, thus to deliver, to the speaker system, an audio output signal from the second filter means.

The first filter means serves to add, to input audio signal, characteristic for conducting a control such that sound image localization position in the case where input audio signal which has been determined in advance by measurement or calculation is reproduced by plural speakers results in an arbitrary position, and the second filter means serves to add correction characteristic of impulse response of the speaker system to output signal of the first filter mans.

Furthermore, the present invention is directed to an audio signal processing apparatus for delivering an audio signal to a speaker system including at least two drive units or more which are divided or separated by frequency band, the audio signal processing apparatus comprising: first filter means having impulse response characteristic of an arbitrary room, which has been determined in advance by measurement or calculation; and second filter means having correction characteristic of impulse response of the speaker system in order to correct shift between phases of respective sound waves radiated from respective drive surfaces of the two drive units or more of the speaker system, thus to deliver, to the speaker system, an audio output signal from the second filter means.

The first filter means serves to add input audio signal to impulse response characteristic of an arbitrary room, which has been determined by measurement or calculation in advance, and the second filter means serves to add correction characteristic of impulse response of the speaker system to output signal of the first filter means.

Furthermore, the present invention is directed to an audio signal processing apparatus for delivering an audio signal to a speaker system including at least two drive units or more which are divided or separated by frequency band, the audio signal processing apparatus comprising: first filter means having impulse response characteristic of an electro-acoustic transducer, which has been determined in advance by measurement or calculation; and second filter means having correction characteristic of impulse response of the speaker system in order to correct shift between phases of respective sound waves radiated from respective drive surfaces of the two drive units or more of the speaker system, thus to deliver, to the speaker system, an audio output signal from the second filter means.

The first filter means serves to add, to input audio signal, impulse response characteristic of the electro-acoustic transducer, which has been determined in advance by measurement or calculation, and the second filter means serves to add correction characteristic of impulse response of the speaker system to output signal of the first filter means.

In the audio signal processing apparatus according to the present invention, since propagation delay time difference does not take place at reproduction frequency bands so that phases of the wave fronts are not collapsed, satisfactory sound image localization can be obtained. Thus, it becomes possible to reproduce an arbitrary transmission characteristic to be added without deteriorating the characteristic. Moreover, it becomes to realize, without deteriorating the characteristic, filter having an arbitrary frequency characteristic in which group delay characteristic to be added is constant. Further, it becomes possible to realize, without deteriorating the characteristic, filter for conducting a control such that sound image localization position in the case where an input audio signal to be added is reproduced by plural speakers results in an arbitrary position. Thus, satisfactory sound image localization characteristic can be obtained. Furthermore, it becomes possible to reproduce, without deteriorating the characteristic, impulse response of an arbitrary room to be added. Thus, it becomes possible to reproduce impulse response of a room equivalent to the impulse response which has been measured. Furthermore, it becomes possible to reproduce, without deteriorating the characteristic, impulse response of electro-acoustic transducer to be added. Thus, it becomes possible to reproduce reproduction sound equivalent to that of the electro-acoustic transducer.

The audio signal reproducing system according to the present invention includes: a speaker system including at least two drive units or more which are divided or separated by frequency band; and a signal processing unit comprising filter means for processing an input audio signal on the basis of correction characteristic of impulse response of the speaker system in order to correct shift between phases of respective sound waves radiated from respective drive surfaces of the two drive units or more of the speaker system, whereby the signal processing unit delivers, to the speaker system, an audio output signal which has been caused to undergo signal processing by the filter means.

Another audio signal reproducing system according to the present invention includes: a speaker system including at least two drive units or more which are divided or separated by frequency band; and a signal processing unit comprising first filter means having an arbitrary transmission characteristic which has been determined by measurement or calculation in advance, and second filter means having correction characteristic of impulse response of the speaker system in order to correct shift between phases of respective sound waves radiated from respective drive surfaces of the two drive units or more of the speaker system, whereby the signal processing unit delivers, to the speaker system, an audio output signal from the second filter means.

In the audio signal processing apparatus according to the present invention, since an input audio signal is processed on the basis of correction characteristic of impulse response, e.g., inverse characteristic of impulse response of the speaker system by the filter means, propagation delay time difference does not take place at reproduction frequency bands of the speaker system so that phases of wave fronts are not shifted. For this reason, satisfactory sound image localization can be obtained.

Moreover, in the audio signal processing apparatus according to the present invention, the first filter means serves to add, to input audio signal, arbitrary transmission characteristic which has been determined in advance by measurement or calculation, and the second filter means serves to add correction characteristic of impulse response of the speaker system to output signal of the first filter means. Accordingly, propagation delay time difference does not take place at reproduction frequency bands so that phases of wave fronts are not shifted. For this reason, satisfactory sound image localization can be obtained. Thus, it becomes possible to reproduce an arbitrary transmission characteristic to be added without deteriorating the characteristic.

Further, in the audio signal processing apparatus according to the present invention, the first filter means serves to add, to an input audio signal, frequency characteristic where group delay characteristic which has been determined in advance by measurement or calculation is constant, and the second filter means serves to add correction characteristic of impulse response of the speaker system to an output signal of the first filter means. Accordingly, it becomes possible to realize, without deteriorating the characteristic, filter having an arbitrary frequency characteristic in which group delay characteristic to be added is constant.

Furthermore, in the audio signal processing apparatus according to the present invention, the first filter means serves to add, to an input audio signal, characteristic for conducting a control such that sound image localization position in the case where an input audio signal is reproduced by plural speakers results in an arbitrary position, and the second filter means serves to add correction characteristic of impulse response of the speaker system to an output signal of the first filter means. Accordingly, it becomes possible to realize, without deteriorating the characteristic, filter for conducting a control such that sound image localization position in the case where an input audio signal to be added is reproduced by plural speakers results in an arbitrary position. Thus, satisfactory sound image localization characteristic can be obtained.

Furthermore, in the audio signal processing apparatus according to the present invention, the first filter means serves to add, to an input audio signal, impulse response characteristic of an arbitrary room, which has been determined in advance by measurement or calculation, and the second filter means serves to add correction characteristic of impulse response of the speaker system to an output signal of the first filter means. Accordingly, it becomes possible to reproduce, without deteriorating the characteristic, impulse response of an arbitrary room to be added. Thus, it becomes possible to reproduce impulse response of a room equivalent to the impulse response which has been measured.

Furthermore, in the audio signal processing apparatus according to the present invention, the first filter means serves to add, to an input audio signal, impulse response characteristic of the electro-acoustic transducer, which has been determined in advance by measurement or calculation, and the second filter means serves to add correction characteristic of impulse response of the speaker system to an output signal of the first filter means. Accordingly, it becomes possible to reproduce, without deteriorating the characteristic, impulse response of the electro acoustic transducer to be added. Thus, it becomes possible to reproduce reproduction sound equivalent to, e.g., electro-acoustic transducer which is called famous article or instrument, or has been difficult to obtain.

Further, the audio signal reproducing system according to the present invention includes signal processing unit comprising filter means for processing an input audio signal on the basis of correction characteristic of impulse response of the speaker system in order to correct shift between phases of respective sound waves radiated from respective drive surfaces of two drive units or more of the speaker system. Accordingly, propagation delay time difference does not take place at reproduction frequency bands of the speaker system so that phases of wave fronts are not shifted. For this reason, satisfactory sound image localization can be obtained.

In addition, the audio signal reproducing system according to the present invention includes signal processing unit comprising first filter means having an arbitrary transmission characteristic which has been determined in advance by measurement or calculation, and second filter means having correction characteristic of impulse response of the speaker system in order to correct shift between phases of respective sound waves radiated from respective drive surfaces of two drive units or more of the speaker system. Accordingly, it becomes possible to reproduce, without deteriorating the characteristic, an arbitrary transmission characteristic to be added.

Still further objects of the present invention and practical merits obtained by the present invention will become more apparent from the description which will be given below with reference to the attached drawings.

### BRIEF DESCRIPTION OF THE DRAWINGS

FIG. 1 is a block circuit diagram showing a two-way speaker system in which drive surfaces of respective drive units do not flush with each other.

FIG. 2 is a block circuit diagram showing a two-way speaker system in which drive surfaces of respective drive units flush with each other.

FIG. 3 is a block circuit diagram showing coaxial arrangement two-way speaker system.

FIG. 4 is a block circuit diagram showing a system for realizing an arbitrary sound image localization by two speakers.

FIG. 5 is a plan view for explaining the principle of the system for realizing an arbitrary sound image localization by two speakers.

FIG. 6 is a block circuit diagram showing an audio signal reproducing system according to the first embodiment of the present invention.

FIG. 7A is a characteristic diagram showing impulse response of multiway speaker system constituting audio signal reproducing system, and FIG. 7B is a characteristic diagram showing amplitude frequency characteristic thereof.

FIG. 8A is a characteristic diagram showing inverse impulse response of the multiway speaker system, and FIG. 8B is a characteristic diagram showing amplitude frequency characteristic thereof.

FIGS. 9A to 9C are views for explaining the principle for calculating inverse characteristic of impulse response.

FIG. 10A is a characteristic diagram showing impulse response near to impulse, and FIG. 10B is a characteristic diagram showing amplitude frequency characteristic thereof.

FIG. 11 is a circuit diagram showing a practical example of digital filter.

FIG. 12 is a block diagram schematically showing signal processing performed within signal processing apparatus constitutining audio signal reproducing system of the second embodiment according to the present invention.

FIG. 13 is a block diagram showing a practical example of signal processing performed within the signal processing apparatus.

FIG. 14A is a characteristic diagram showing amplitude characteristic of filter in which group delay characteristic is constant, and FIG. 14B is a characteristic diagram showing impulse response thereof.

FIG. 15 is a block circuit diagram showing an audio signal reproducing system of the third embodiment according to the present invention.

FIG. 16 is a block circuit diagram showing the internal configuration of signal processing apparatus constituting the audio signal reproducing system of the third embodiment according to the present invention.

FIG. 17 is a block circuit diagram showing an audio signal reproducing system of the ninth embodiment according to the present invention.

### BEST MODE FOR CARRYING OUT THE INVENTION

Several embodiments for carrying out the invention will now be explained.

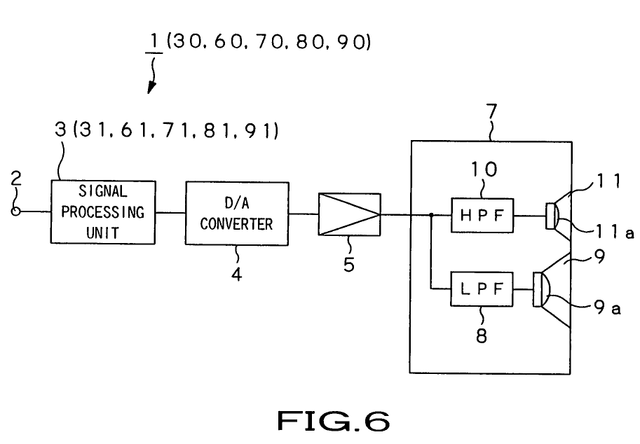

The first embodiment is directed to an audio signal reproducing system 1 as shown in FIG. 6. While explanation will be given in the audio signal reproducing system 1 on the assumption that digital audio signal is handled as input signal, analog audio signal can be similarly handled by initially performing A/D converting processing.

In FIG. 6, the audio signal reproducing system 1 comprises a signal processing unit (apparatus) 3 for adding characteristic which will be described later to a digital audio signal inputted from an input terminal 2, a D/A converter 4 for converting a processed output from the signal processing unit 3 into an analog signal, a power amplifier 5 for amplifying the analog signal from the D/A converter 4, and a two-way speaker system 7 composed of a unit for driving a signal at low frequency band (hereinafter simply referred to as a low frequency drive unit or driver) 9 connected to a LPF8 and a unit for driving a signal at high frequency band (hereinafter simply referred to as a high frequency drive unit or driver) 11 connected to a HPF10.

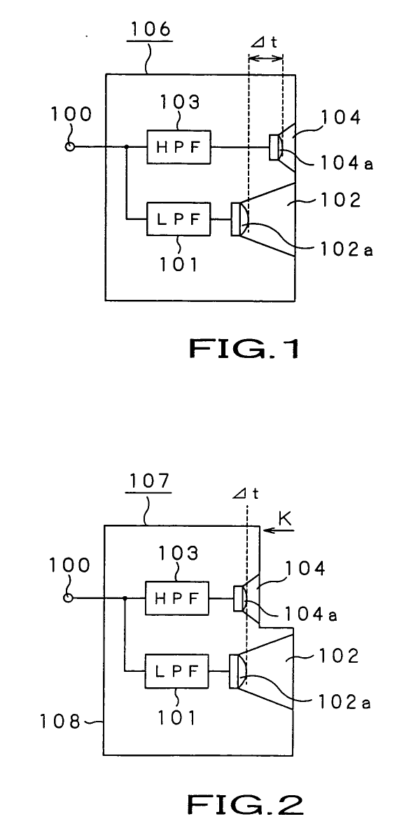

The two-way speaker system 7 is directed to a speaker in which, similarly to the above-described two-way speaker system 106 shown in FIG. 1, a drive surface 9a of the low frequency drive unit 9 and a drive surface 11a of the high frequency drive unit 11 do not flush with each other, and propagation delay time difference Δt between at low reproduction frequency band and at high reproduction frequency band takes place so that phase difference between sound waves takes place.

In the audio signal reproducing system 1 of such configuration, the signal processing unit 3 serves to add, e.g., inverse characteristic, as correction characteristic of impulse response of the speaker system 7 to a digital audio signal inputted from the input terminal 2. Thereafter, the D/A converter converts the digital audio signal thus obtained back into an analog signal. The power amplifier 5 serves to amplify the analog signal thus obtained thereafter to deliver it to the speaker system 7. The speaker system 7 outputs a signal at the low frequency band that the LPF8 has passed from the drive surface 9a of the low frequency drive unit 9 as sound wave of low pitched sound, and outputs a signal at high frequency band that the HPF10 has passed from the drive surface 11a of the high frequency drive unit 11 as sound wave of high pitched sound.

As correction characteristic to be added, there is used inverse characteristic of characteristic determined by measuring or calculating in advance overall impulse response of the speaker system 7 in the case where both the high frequency drive unit 11 and the low frequency drive unit 9 are driven at the same time.

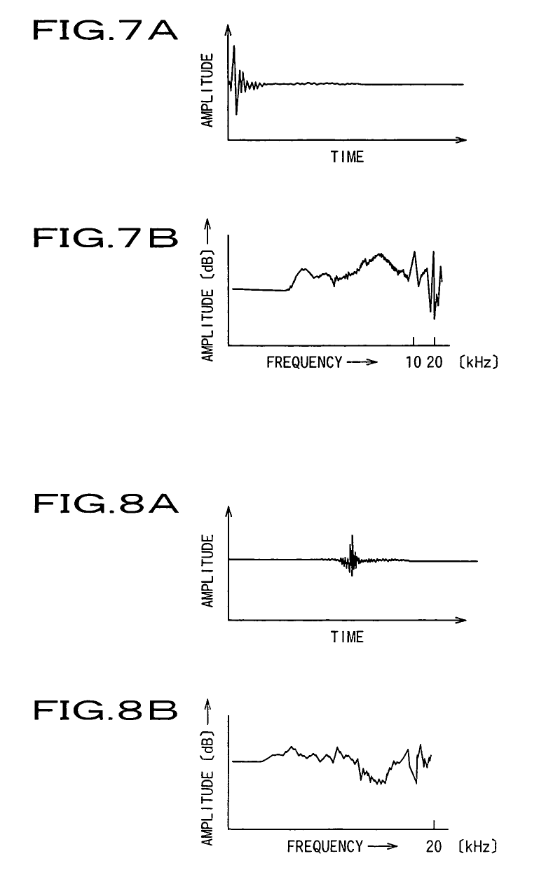

For example, it is assumed that the speaker system 7 shown in FIG. 6 has impulse response shown in FIG. 7A and frequency characteristic shown in FIG. 7B which is representation of corresponding frequency region. When the inverse characteristic of the impulse response shown in FIG. 7A is calculated, impulse response (inverse impulse response) shown in FIG. 8A can be obtained. FIG. 8B in this case shows amplitude frequency characteristic.

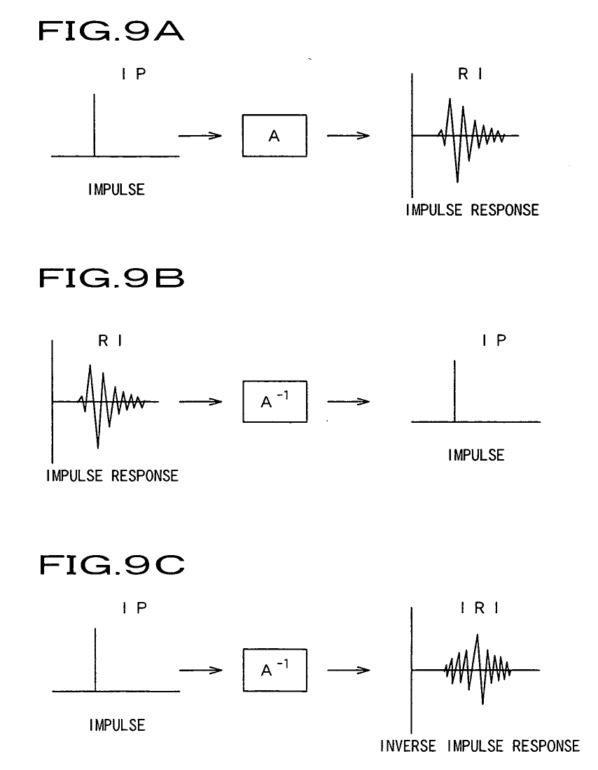

Calculation of the inverse characteristic of impulse response is performed on the basis of the principle as described below. When impulse IP shown in FIG. 9A is inputted to the function A, impulse response RI is obtained. The transfer function for converting the impulse response RI back into impulse IP as shown in FIG. 9B is assumed to be inverse function A-1. When impulse IP is inputted to the inverse function A-I as shown in FIG. 9C, inverse impulse response IRI is obtained. It is to be noted that, at the frequency band of low pitched sound, roll-off is performed on the basis of restriction such as reproduction ability of the low frequency drive unit 9, e.g., non-linear distortion characteristic or tolerable input level, etc.

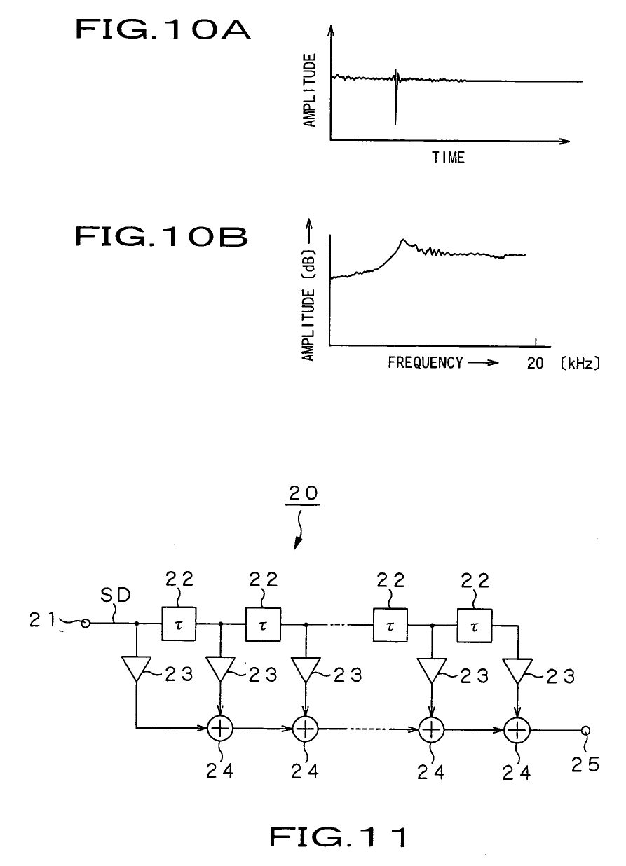

In the signal processing unit 3, inverse characteristic of impulse response (inverse impulse response) IRI is realized by digital filter. When the inverse impulse response is inputted to the speaker system 7 having function A, impulse IP can be obtained. Thus, in the case where the characteristic of the speaker is measured at the same measurement point, flat amplitude frequency characteristic as shown in FIG. 10B and impulse response characteristic near to impulse shown in FIG. 10A can be obtained.

Then, the signal processing unit 3 of the audio signal reproducing system 1 for realizing inverse characteristic of impulse response will be explained. In concrete terms, the signal processing unit 3 serves to realize the inverse characteristic of the impulse response by using, e.g., digital filter 20 as shown in FIG. 11.

In the digital filter 20 shown in FIG. 11, a digital audio signal SD is serially delivered to plural delay circuits 22˜22 through an input terminal 21. In addition, signals obtained from the terminal 21 and the delay circuits 22˜22 are delivered to multiplier circuits 23˜23. Thus, multiplication outputs are taken out to an output terminal 25 through adding circuits 24˜24. In this case, the delay circuits 22˜22 serve to give delay of one sampling period (one unit period) τ to digital audio signal SD. The multiplier circuits 23˜23 have inverse characteristic of the impulse response as coefficients.

In ideal two-way speaker system 107 in which drive surface 102a of the low frequency drive unit 102 and drive surface 104a of the high frequency drive unit 104 which have been shown in the previously mentioned FIG. 2 flush with each other, when spreads in terms of time of impulse responses that individual drive units themselves have are neglected, it should be considered that shifts of phases as described above do not take place. Accordingly, when impulse is inputted, impulse would be outputted as it is in place of impulse response having spread in terms of time as shown in FIG. 7A.

This fact means the following matter. Namely, even in the case of the multiway speaker system shown in FIG. 6, if impulse is inputted so that impulse is outputted, there results the state equivalent to the fact that drive surface 9a of the low frequency drive unit 9 and drive surface 11a of the high frequency drive unit 11 flush with each other.

Accordingly, even in the multiway speaker system 7, deterioration of transmission characteristic due to difference between transmission delay times by plural speaker drive units is improved so that it can be said that the equiphase characteristic of respective units is substantially ensured. For this reason, an audio signal is inputted to a system comprised of audio signal reproducing system 1 in which digital filter 20 shown in FIG. 11 is constituted by the signal processing unit 3, thereby making it possible to obtain a speaker reproducing system having satisfactory sound image localization and sound quality.

It is to be noted that while there is employed the multiway system comprising LPF8 and HPF10 for convenience of explanation in the above-mentioned embodiment, either one of filters or both filters may be omitted in dependency upon reproduction frequency characteristic of respective drive units. Also in that case, the present invention can be applied.

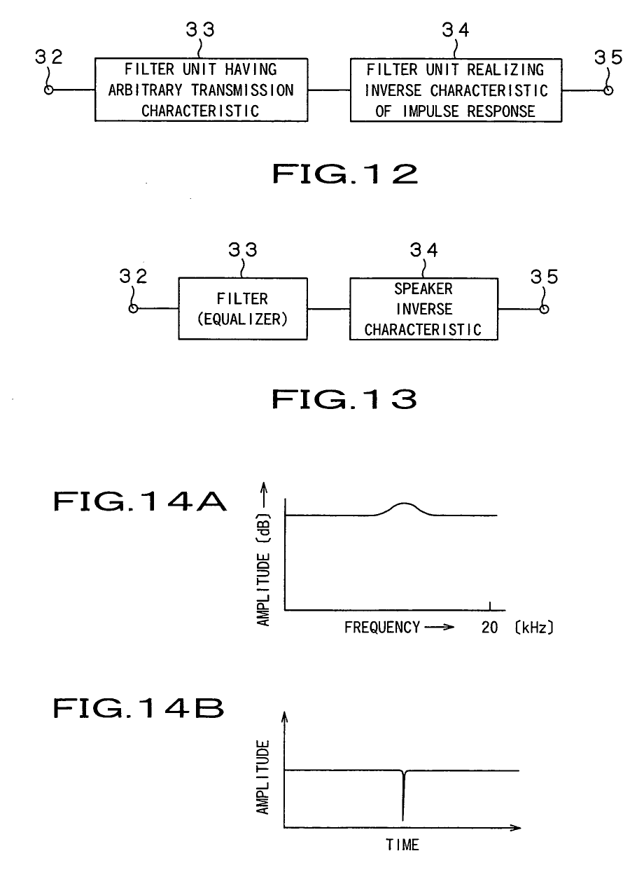

Then, the second embodiment of the present invention will be explained. The second embodiment is directed to an audio signal reproducing system 30 in which the system configuration is similar to that shown in FIG. 6. The audio signal reproducing system 30 differs from the audio signal reproducing system 1 of the first embodiment in the signal processing within the signal processing unit 31. As shown in FIG. 12, signal processing at the signal processing unit 31 is performed by a filter unit 33 having an arbitrary transmission characteristic which has been determined by measurement or calculation in advance, and a filter unit 34 for realizing inverse characteristic of impulse response of the multiway speaker system. An arbitrary transmission characteristic that the filter unit 33 has determined by calculation is added to a digital audio signal SD inputted from the input terminal 32. The filter unit 34 serves to add inverse characteristic of the impulse response. In concrete terms, as shown in FIG. 13, the filter unit 33 functions as an equalizer unit to add, to the digital audio signal SD, frequency characteristic that user has arbitrarily set. Moreover, the filter unit 34 serves to add inverse characteristic of the multiway speaker system 7 which has been explained in the first embodiment to output digital audio signal of the filter unit 33.

The equalizer function that the filter unit 33 performs will be explained. The filter unit 33 serves to add such a frequency characteristic that group delay characteristic is constant to the digital audio signal SD in performing equalizer processing, e.g., processing to add amplitude frequency characteristic which takes peak in the vicinity of frequency of 1 KHz as shown in FIG. 14A.

The fact that the group delay characteristic is constant means that delay time is not changed by the frequency band so that the phase relationship is not collapsed by the frequency band. In the filter in which the group delay characteristic is constant, in the case of the FIR filter in which, e.g., the number of taps is odd, respective multiplication coefficients are symmetrical in left and right directions with the (number of taps +1)/2-th multiplier circuit being as center. Of course, even in the case where the number of taps is even, respective multiplication coefficients are symmetrical in left and right directions. The FIR filter having the number of taps of 2 t has group delay time corresponding to t tap. Such a filter in which group delay characteristic is constant can be realized by using FIR filter as shown in FIG. 11.

The inverse characteristic of the multiway speaker system that the filter unit 34 has has been already explained. The inverse characteristic is added to an input signal by the FIR filter 20 shown in FIG. 1 to realize impulse response as shown in FIG. 14B. For this reason, it is possible to almost neglect the characteristic specific to the multiway speaker system.

As a result, the audio signal reproducing system 30 of the second embodiment serves to allow the signal processing unit 31 to function (perform) processing shown in FIGS. 12 and 13 to exclude impulse response specific to the multiway speaker system in speaker output to have ability to provide an only output in which the group delay characteristic is constant. Thus, also in the case where an arbitrary frequency characteristic is added, there would result no possibility that phase is shifted by a specific frequency. As a result, it is possible to obtain multiway speaker system excellent in both sound quality and sound image localization.

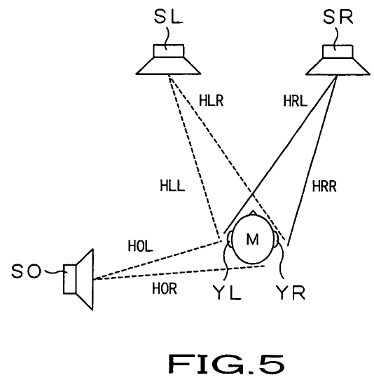

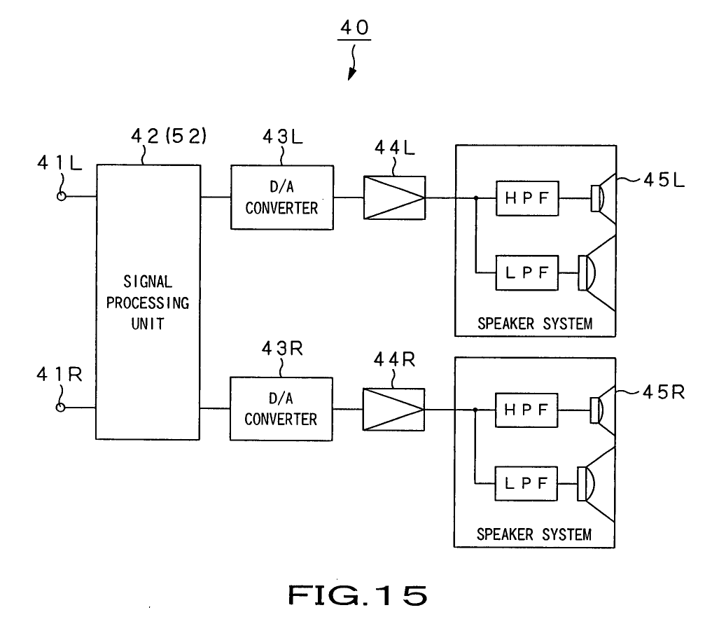

Then, the third embodiment according to the present invention will be explained. The third embodiment is directed to an audio signal reproducing system 40 of the configuration shown in FIG. 15 in which two speakers are used to constitute virtual speaker sound source to allow sound image to undergo localization such that there results an arbitrary position. This system is a system in which when sound image SO is virtually reproduced by using sound source SL and sound source SR as shown in the previously mentioned FIG. 5, impulse responses specific to left and right speaker systems are excluded to obtain satisfactory sound localization characteristic.

For this reason, the audio signal reproducing system 40 comprises a signal processing unit 42 for implementing processing to allow sound image by audio signal for Lch inputted from an input terminal 41L and audio signal for Rch inputted from an input terminal 41R to undergo localization such that there results an arbitrary position and for neglecting the influence of the two speaker systems, a D/A converter 43L and a D/A converter 43R which serve to convert processed output for Lch and processed output for Rch from the signal processing unit 42 into analog signals, an amplifier 44L and an amplifier 44R which serve to amplify the analog signals from the D/A converter 43L and the D/A converter 43R, and multiway speaker systems 45L and 45R for converting amplification outputs from the amplifiers 44L and 44R into sound waves.

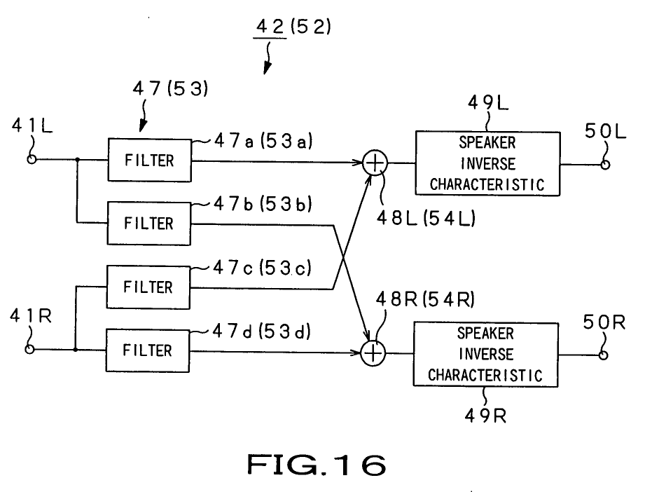

In order to allow sound image to undergo localization such that there results an arbitrary position, as shown in FIG. 16, the signal processing unit 42 includes a filter unit 47 composed of filters 47a, 47b, 47c and 47d. The filter unit 47 constitutes sound image localization filter having characteristic for allowing sound image to undergo localization such that there results an arbitrary position by using two speakers by filters 47a, 47b, 47c and 47d. The filters 47a, 47b serve to convolutes impulse response in which transfer function similar to the transfer function portion of the above-described formulas (1) and (2) is converted into the time axis with respect to digital signal SL from the input terminal 41L. The filters 47c, 47d serve to convolute impulse response in which transfer function similar to the transfer function portion of the formulas (1) and (2) is converted into the time axis with respect to digital signal SR from the input terminal 41R. An adder 48L adds filter output of the filter 47a and filter output of the filter 47c. An adder 48R adds filter output of the filter 47b and filter output of the filter 47d.

The adder 48L calculates added output corresponding to the formula described below.
HOL×SO=HLL×SL+HRL×SR (3)

The adder 48R calculates added output corresponding to the formula described below.
HOR×SO=HLR×SL+HRR×SR (4)

The formula (3)×HRR−the formula (4)×HRL is represented as follows.
(HOL×HRR−HOR×HRL)SO=(HLL×HRR−HLR×HRL)SL
Transformation of this representation gives the formula (1).

The formula (4)×HLL−the formula (3)×HLR is represented as follows.
(HOR×HLL−HOR×HLR)SO=(HLL×HRR−HLR×HRL)SR.
Transformation of this representation gives the formula (2).

Accordingly, audio signal Sao of the sound source SO results in synthetic audio signal for left ear by passing it through the system of the adder 48L, and results in synthetic audio signal for right ear by passing it through the adder 48R. Namely, two speakers disposed at the positions of the sound sources SL and SR are driven, thereby making it possible to allow virtual sound source as if audio signal Sao is produced from the position of the sound source SO to undergo localization.

Further, at the signal processing unit 42, synthetic audio signal for left ear is passed through a filter 49L for adding inverse characteristic of the multiway speaker system 45L, and synthetic audio signal for right ear is passed through a filter 49R for adding inverse characteristic of the multiway speaker system 45R.

The speaker inverse characteristic is as explained in the above-described first and second embodiments. Accordingly, an output of the realized sound image localization filter is delivered to the multiway speaker systems 45L, 45R through the speaker inverse characteristic. Thus, influence of the speaker characteristic can be neglected. As a result, it becomes possible to obtain satisfactory sound image localization characteristic.

It is to be noted that while two speakers are used at the filter unit to constitute sound image localization filter having characteristic for allowing sound image to undergo localization such that there results an arbitrary position, processing may be similarly performed also in the case where the number of sound sources is 1 (one), or 3 (three) or more. Respective sound image localization filters may be constituted by using FIR filter as shown in FIG. 11.

Then, the fourth embodiment according to the present invention will be explained. The fourth embodiment is directed to an audio signal reproducing system 51 in which the system configuration is similar to that shown in FIG. 15. The audio signal reproducing system 51 differs from the audio signal reproducing system 40 of the third embodiment in a portion of signal processing within the signal processing unit 52. The outline of the configuration of the signal processing unit 52 is similar to that of FIG. 16, but the former differs from the latter in that the filter unit 53 processes, by FIR filter, impulse response of a hall or an arbitrary room which has been determined by measurement or calculation. Filters 53a, 53b of the filter unit 53 reproduce transfer functions from left side sound source to left ear and right ear of listener by the impulse response of hall or arbitrary room which has been measured or calculated to convolute it with respect to digital signal. Moreover, the filters 53c and 53d reproduce transfer functions from the right side sound source to left ear and right ear of listener by impulse response of a hall or an arbitrary room which has been measured or calculated to convolute it with respect to digital signal. An adder 54L adds filter output of the filter 53a and filter output of the filter 53c. An adder 54R adds filter output of the filter 53b and filter output of the filter 53d. In a manner as stated above, the signal processing unit 52 can reproduce sound having sound field characteristic under different environment such as hall or arbitrary room, etc. Since sounds of reproduction multiway speaker systems 45L, 45R are further added to the above-mentioned sound in such state so that correct sound field reproduction becomes difficult, the signal processing unit 52 serves to pass added output of the adder 54L and added output of the adder 54R through filter 49L for adding inverse characteristic of the multiway speaker system 45L and filter 49R for adding inverse characteristic of the multiway speaker system 45R.

The speaker inverse characteristic is as explained in the above-described first and second embodiments. Accordingly, realized sound field localization filter output is delivered to multiway speaker systems 45L, 45R through the speaker inverse characteristic. Thus, the influence of the speaker characteristic can be neglected. As a result, it becomes possible to obtain satisfactory sound filed characteristic near to the environment where sound filed is measured.

Then, the fifth embodiment according to the present invention will be explained. The fifth embodiment is directed to an audio signal reproducing system 60 in which the system configuration is similar to that shown in FIG. 6. The audio signal reproducing system 60 differs from the audio signal reproducing systems 1 and 30 of the first and second embodiments in signal processing within the signal processing unit 61.

As shown in FIG. 12, processing at the signal processing unit 61 is performed by filter unit 33 having arbitrary transmission characteristic which has been determined in advance by measurement or calculation, and filter unit 34 for realizing inverse characteristic of impulse response of the speaker. In more detail, similarly to FIG. 13, the filter unit 33 functions as equalizer unit, and serves to add frequency characteristic that user arbitrarily set to digital audio signal. Moreover, the filter unit 34 serves to add inverse characteristic of the multiway speaker system 7 which has been explained in the first embodiment to an output digital audio signal of the filter unit 33.

In this example, at the filter unit 33, impulse response of other speaker which has been determined by measurement or calculation is realized by FIR filter as shown in FIG. 11. Impulse response of a speaker which is called famous article or instrument is realized by FIR filter of the filter unit 33. Further, an audio signal to which realized speaker impulse response has been added is delivered to multiway speaker systems 45L, 45R through filter 49L for adding the inverse characteristic of the multiway speaker system 45L and filter 49R for adding the inverse characteristic of the multiway speaker system 45R. Thus, the influence of the speaker characteristic can be neglected. As a result, it becomes possible to reproduce, extremely with high fidelity, other speaker characteristic which is called famous article or instrument.

Then, the six embodiment according to the present invention will be explained. The sixth embodiment is directed to an audio signal reproducing system 70 in which the system configuration is also similar to that shown in FIG. 6. The audio signal reproducing system 70 also differs from the audio signal reproducing systems 1, 30 and 60 of the first, second and fifth embodiments in signal processing within the signal processing unit 71.

As shown in FIG. 12, processing at the signal processing unit 71 is performed by filter unit 33 having an arbitrary transmission characteristic which has been determined by measurement or calculation in advance, and filter unit 34 for realizing inverse characteristic of impulse response of the speaker. In more detail, similarly to FIG. 13, the filter unit 33 functions as an equalizer unit, and serves to add frequency characteristic that user has arbitrarily set to digital audio signal. Moreover, the filter unit 34 serves to add inverse characteristic of the multiway speaker system 7 which has been explained in the above-mentioned embodiment to output digital audio signal of the filter unit 33.

In this example, at the filter unit 33, impulse response of record needle which has been determined by measurement or calculation is realized by FIR filter. Impulse response of record needle which is so called famous article or instrument, or record needle difficult to obtain at present is realized by FIR filter. Further, an audio signal to which realized impulse response of record needle has been added is delivered to multiway speaker systems 45L, 45R through filter 49L for adding inverse characteristic of the multiway speaker system 45L and filter 49R for adding inverse characteristic of the multiway speaker system 45R. Thus, the influence of the speaker characteristic can be neglected. As a result, it becomes possible to reproduce, extremely with high fidelity, the primary characteristic of the record needle to hear corresponding sound.

Then, the seventh embodiment according to the present invention will be explained. The seventh embodiment is directed to an audio signal reproducing system 80 in which the system configuration is similar to that shown in FIG. 6. The audio signal reproducing system 80 differs from the audio signal reproducing systems 1, 30, 60 and 70 of the first, second, fifth and sixth embodiment in signal processing within the signal processing unit 81.

As shown in FIG. 12, signal processing at the signal processing unit 81 is performed by filter unit 33 having arbitrary transmission characteristic which has been determined in advance by measurement or calculation, and filter unit 34 for realizing inverse characteristic of impulse response of the speaker. In more detail, similarly to FIG. 13, the filter unit 33 functions as an equalizer unit, and serves to add frequency characteristic that user has ordinarily set to digital audio signal. Moreover, the filter unit 34 serves to add inverse characteristic of the multiway speaker system 7 which has been explained in the first embodiment to an output digital audio signal of the filter unit 33.

In this example, at the filter unit 33, impulse response of recording/reproducing device or instrument which has been determined by measurement or calculation is realized. The recording/reproducing device is record player, tape recorder, CD player or MD player, etc. There may be employed recording/reproducing device which is so called famous article or instrument, or recording/reproducing device difficult to obtain at present. The impulse response may be realized by the FIR filter of the filter unit 33. Further, an audio signal to which realized impulse response of the recording/reproducing device has been added is delivered to the multiway speaker systems 45L, 45R through filter 49L for adding the inverse characteristic of the multiway speaker system 45L and filter 49R for adding the inverse characteristic of the multiway speaker system 45R. Thus, the influence of the speaker characteristic can be neglected. As a result, it is possible to reproduce, extremely with high fidelity, the primary characteristic of the recording/reproducing device to hear it.

Then, the eighth embodiment of the present invention will be explained. The eighth embodiment is directed to an audio signal reproducing system 90 in which the system configuration is similar to that shown in FIG. 6. The audio signal reproducing system 90 differs from the audio signal reproducing systems 1, 30, 60, 70 and 80 in signal processing within the signal processing unit 91.

The signal processing performed at the signal processing unit 91 is as shown in FIG. 12. The detail thereof is similar to that of FIG. 13. In this example, at the filter unit 33, impulse response of amplifier which has been determined by measurement or calculation is realized by FIR filter. There may be employed an amplifier which is so called famous article or decvice, or amplifier difficult to obtain at present. Impulse response of such amplifier is realized by the FIR filter of the filter unit 33. Further, an audio signal to which realized impulse response of the amplifier has been added is delivered to multiway speaker systems 45L, 45R through filter 49 for adding the inverse characteristic of the multiway speaker system 45L and filter 49R for adding the inverse characteristic of the multiway speaker system 45R. Thus, the influence of the speaker characteristic can be neglected. As a result, it becomes possible to reproduce, extremely with high fidelity, primary characteristic of the amplifier to hear it.

Then, the ninth embodiment according to the present invention will be explained. The ninth embodiment is directed to an audio signal reproducing system in which there is employed a configuration such that impulse responses of plural electro-acoustic transducers, which have been determined by measurement or calculation, are realized by FIR filter, and coefficients of the filter for determining impulse response are permitted to be varied, thus to selectively and variably reproduce characteristics of plural electro-acoustic transducers by selection of user or rewriting coefficients. The electro acoustic transducer is speaker, headphone system, record needle, recording/reproducing device, device with frequency characteristic and/or amplifier, etc.

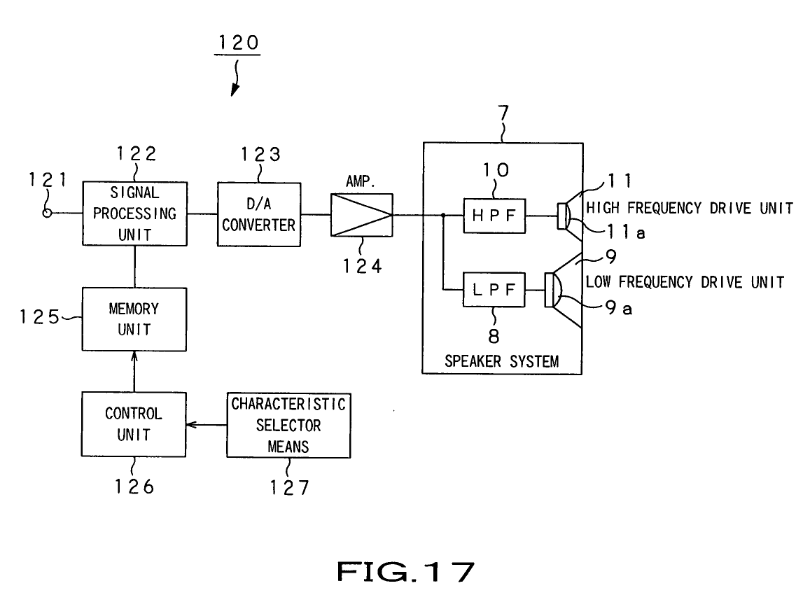

As shown in FIG. 17, the audio signal reproducing system 120 comprises a signal processing unit 122 for adding the characteristic which will be described later to a digital audio signal inputted from an input terminal 121, a D/A converter 123 for converting processed output from the signal processing unit 122 into an analog signal, a power amplifier 124 for amplifying the analog signal from the D/A converter 123, and a two-way speaker system 7 composed of low frequency drive unit 9 connected to LPF8 and high frequency drive unit 11 connected to HPF10.

Further, the audio signal reproducing system 120 comprises a memory unit 125 serving as work area for storing characteristics of impulse responses of plural electro-acoustic transducers and for rewriting impulse response characteristics, a control unit 126 serving to conduct a control for selecting impulse response stored in the memory unit 125 and for rewriting it, and characteristic selector means 127 for selecting characteristic by the impulse response by taste of user through the control unit 126.

As shown in FIG. 12, signal processing at the signal processing unit 122 is performed by filter unit 33 having arbitrary transmission characteristic which has been determined in advance by measurement or calculation, and filter unit 34 for realizing the inverse characteristic of the impulse response of the speaker. In more detail, similarly to FIG. 13, the filter unit 33 functions as an equalizer unit, and serves to add frequency characteristic that user has arbitrarily set to digital audio signal. Moreover, the filter unit 34 serves to add the inverse characteristic of the multiway speaker which has been explained in the above-mentioned first embodiment to an output digital audio signal of the filter unit 33.

In this example, at the filter unit 33, impulse responses of plural electro-acoustic transducers which have been determined by measurement or calculation are realized by FIR filter. The impulse responses of the plural electro-acoustic transducers used in this filter are permitted to be freely varied by control from the control unit 126. Since plural impulse response data are stored in memory unit 125, user selects characteristic among them in accordance with sound source or taste by characteristic selector means 127 under control of the control unit 126. Coefficients within the signal processing unit are rewritten by impulse response characteristic which has been selected from the memory unit 125 to thereby bring into the state where sound can be heard by new coefficients. This output is delivered to the multiway speaker system 7 through filter unit 34 for adding the inverse characteristic of the multiway speaker system 7. Thus, the influence of the speaker characteristic can be neglected. As a result, it becomes possible to selectively reproduce, extremely with high fidelity, primary characteristic of plural electro-acoustic transducers to hear it.

For example, in the case where speaker is used as the electro-acoustic transducer, it becomes possible to freely select speaker characteristic which is considered to be preferable in accordance with music source, etc. to add the speaker characteristic thus selected. As a result, as compared to the case where plural speakers are provided to perform switching therebetween to hear sound, a function as described above can be realized by remarkably simple method.

While explanation has been given in the above-described series of explanations in the state where division into the filter unit and the speaker inverse characteristic unit of FIG. 12 is performed for convenience of explanation, it is a matter of course that synthetic characteristic obtained by performing synthesis (convolution integral) of both characteristics may be realized also by using one filter means.

It is to be noted that filter arrangement which has been explained with reference to FIGS. 12, 13 and 16 may be exchanged in the above-described embodiments. For example, speaker inverse characteristic filter unit 34 may be placed at the preceding stage of the filter unit 33 of FIG. 13. Moreover, it is matter of course to combine these filter characteristics to constitute it as single filter.

In addition, while there is employed, in the above-described respective embodiments, similarly to the two-way speaker system 106 shown in FIG. 1, multiway speaker system in which drive surface 9a of the low frequency drive unit 9 and drive surface 11a of the high frequency drive unit 11 do not flush with each other, coaxial arrangement two-way speaker system as shown in the FIG. 15 may be used. The coaxial arrangement two-way speaker is a system in which the high frequency drive unit 104 and the low frequency drive unit 102 are coaxially disposed so that their drive axes flush with each other as described above. Since the high frequency drive unit 104 is disposed at the front face of the low frequency drive unit 102 from a structural point of view, drive surface of sound wave of the high frequency drive unit 104 and drive surface of sound wave of the low frequency drive unit 102 are shifted. As a result, propagation delay time difference Δt would take place. For this reason, phases of wave fronts of sound waves are necessarily shifted by reproduction frequency band. This is not preferable in order to obtain satisfactory sound image localization.

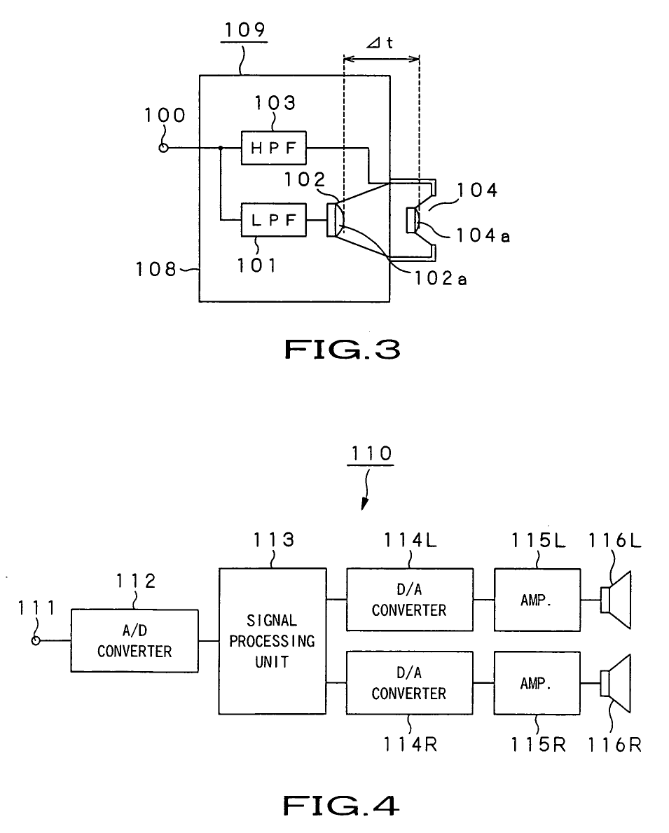

In the respective embodiments of the present invention, even in the case of deterioration of transmission characteristic due to difference between transmission delay times by plural speaker drive units shown in FIG. 3, such a deterioration can be improved. The equiphase characteristic of respective units is substantially ensured. For this reason, an audio signal is inputted to a system comprised of audio signal reproducing system 1, etc. in which digital filter 20 is constituted by signal processing unit 3, etc., thereby making it possible to obtain a speaker reproducing system having satisfactory sound image localization and sound quality.

It is to be noted that while the invention has been described in accordance with certain preferred embodiments thereof illustrated in the accompanying drawings and described in the above description in detail, it should be understood by those ordinarily skilled in the art that the invention is not limited to the embodiments, but various modifications, alternative constructions or equivalents can be implemented without departing from the scope and spirit of the present invention as set forth and defined by the appended claims.

1 An audio signal processing apparatus adapted for delivering an audio signal to a speaker system including at least two drive units or more which are divided or separated by frequency band,
the audio signal processing apparatus comprising:
filter means for processing the input audio signal on the basis of correction characteristic of impulse response of the speaker system in order to correct shift between phases of respective sound waves radiated from respective drive surfaces of the two drive units or more of the speaker system,
thus to deliver, to the speaker system, an audio output signal which has been caused to undergo signal processing by the filter means.

2 The audio signal processing apparatus as set forth in claim 1,
wherein the two drive units or more are caused to be of the configuration in which a drive unit for reproducing a signal at high frequency band and a drive unit for reproducing a signal at low frequency band are attached in the state where they are coaxially disposed.

3 The audio signal processing apparatus as set forth in claim 1,
wherein the filter means serves to realize correction characteristic of the impulse response by FIR filter to process the input audio signal.

4 An audio signal processing apparatus adapted for delivering an audio signal to a speaker system including at least two drive units or more which are divided or separated by frequency band,
the audio signal processing apparatus comprising: first filter means having an arbitrary transmission characteristic which has been determined in advance by measurement or calculation; and second filter means having correction characteristic of impulse response of the speaker system in order to correct shift between phases of respective sound waves radiated from respective drive surfaces of the two drive units or more of the speaker system, thus to deliver, to the speaker system, an audio output signal from the second filter means.

5 The audio signal processing apparatus as set forth in claim 4,
wherein transmission characteristic that the first filter means has is frequency characteristic in which group delay characteristic is constant.

6 The audio signal processing apparatus as set forth in claim 4,
wherein transmission characteristic that the first filter means has is characteristic for conducting a control such that sound image localization position in the case where an input audio signal is reproduced by plural speakers results in an arbitrary position.

7 The audio signal processing apparatus as set forth in claim 4,
wherein transmission characteristic that the first filter means has is impulse response characteristic of an arbitrary room.

8 The audio signal processing apparatus as set forth in claim 4,
wherein transmission characteristic that the first filter means has is impulse response characteristic of an electro-acoustic transducer.

9 The audio signal processing apparatus as set forth in claim 8,
wherein impulse response characteristic of an electro-acoustic transducer which is transmission characteristic that the first filter means has is impulse response characteristic of speaker or headphone system.

10 The audio signal processing apparatus as set forth in claim 8,
wherein impulse response characteristic of an electro-acoustic transducer which is transmission characteristic that the first filter means has is impulse response characteristic of record needle.

11 The audio signal processing apparatus as set forth in claim 8,
wherein impulse response characteristic of an electro-acoustic transducer which is transmission characteristic that the first filter means has is impulse response characteristic of recording/reproducing device.

12 The audio signal processing apparatus as set forth in claim 8,
wherein impulse response characteristic of an electro-acoustic transducer which is transmission characteristic that the first filter means has is impulse response characteristic of a frequency characteristic adding unit.

13 The audio signal processing apparatus as set forth in claim 8,
wherein impulse response characteristic of an electro-acoustic transducer which is transmission characteristic that the first filter means has is impulse response characteristic of an audio amplifier.

14 The audio signal processing apparatus as set forth in claim 4,
wherein the first filter means serves to add, to the input audio signal, impulse response characteristic which has been selectively switched among impulse response characteristics of plural kinds of electro-acoustic transducers.

15 The audio signal processing apparatus as set forth in claim 4,
wherein the first filter means and the second filter means are comprised of FIR filter.

16 An audio signal reproducing system including:
a speaker system including at least two drive units or more which are divided or separated by frequency band; and
a signal processing unit comprising filter means for processing the input audio signal on the basis of correction characteristic of impulse response of the speaker system in order to correct shift between phases of respective sound waves radiated from respective drive surfaces of the two drive units or more of the speaker system,
whereby the signal processing unit delivers, to the speaker system, an audio output signal which has been caused to undergo signal processing by the filter means.

17 An audio signal reproducing system including:
a speaker system including at least two drive units or more which are divided or separated by frequency band; and
a signal processing unit comprising first filter means having an arbitrary transmission characteristic which has been determined in advance by measurement or calculation, and second filter means having correction characteristic of impulse response of the speaker system in order to correct shift between phases of respective sound waves radiated from respective drive surfaces of the two drive units or more of the speaker system,
whereby the signal processing unit delivers, to the speaker system, an audio output signal from the second filter means.
